(19) United States
(12) Patent Application Publication
(10) Pub. No.: US 2011/0080088 A1
(43) Pub. Date: Apr. 7, 2011

(54) ORGANIC EL PANEL AND PANEL - COMBINED LIGHT- EMITTING DEVICE

(75) Inventors: Zenichiro Hara, Tokyo (JP); Satoru Kiridoshi, Tokyo (JP); Suguru Nagae, Tokyo (JP); Takanori Okumura, Tokyo (JP); Shintaro Yamasaki, Tokyo (JP); Yutaka Saito, Yamagata-ken (JP); Yuji Saito, Yamagata-ken (JP); Hiroyuki Sato, Yamagata-ken (JP); Yosuke Sato, Yamagata-ken (JP); Masami Kimura, Yamagata-ken (JP); Jun Sugahara, Yamagata-ken (JP)

(73) Assignees: Mitsubishi Electric Corporation, Tokyo (JP); Tohoku Pioneer Corporation, Tendo-shi (JP)

(21) Appl. No.: 12/719,752

(22) Filed: Mar. 8, 2010

(30) Foreign Application Priority Data
Oct. 5, 2009 (JP) 2009-231480

(51) Int. Cl. H01L 51/52

(52) U.S. Cl. 313/504

(57) ABSTRACT

An organic EL panel (light transmissive luminescent panel) is configured to have a display screen formed of a plurality of pixels with improved display performance by restricting stray light at the panel edge surface and enabling a high-grade color display by restricting the reduction of the mixing ratio of colors. The organic EL panel is of a light-transmissive type with organic EL elements formed on the panel substrate, The display screen is configured by a plurality of pixels which are organic EL elements, The right and left edge faces of the panel substrate or the sealing substrate are made to be light-absorbent or light non-transmissive, The light-emitting surface of the organic EL element is made in a horizontally elongated shape with a longitudinal direction orthogonal to a direction along the right and left edge faces,

### FIELD OF THE INVENTION

The invention is related to an organic EL panel and a panel-combined light-emitting device.

### BACKGROUND OF THE INVENTION

A light transmissive luminescent panel (hereinafter referred to as “luminescent panel”) is known that is configured to transmit light outward through a panel substrate made of a light transmissive material from a light-emitting element disposed on one side of the panel substrate such that the light emission of the light-emitting element is directed to the other side of the panel substrate. An organic EL panel called a “bottom emission type” is an example of such a panel, and includes an organic EL element formed on one side of the panel substrate with a transparent electrode, an organic layer including an emitting layer and a metallic electrode serially laminated thereon, transmitting light from the organic EL element outward through the panel substrate.

FIG. 1 is a view to explain a problem with regard to the above-mentioned luminescent panel. In the luminescent panel, light emitted from a light-emitting element J2 passes through a panel substrate J1 by various routes as shown in FIG. 1(a). This includes not only light that passes through a front face of the panel substrate J1 to enter a field of view (light L1 and L2), but also stray light that passes along different routes by reflecting on or passing through an edge face J1a of the panel substrate J1 to enter the field of view (light L1s and L2s). Accordingly, the stray light may significantly degrade the display quality when the luminescent panel is used as a display device.

A countermeasure against the stray light of the luminescent panel has been devised to make the edge face J1a light-absorbent or light non-transmissive as shown in FIG. 1(b). Specifically, the edge face J1a is stained black to be light-absorbent or a light-absorbent or light non-transmissive member S is attached to the edge face J1a, thereby preventing the light arriving onto the edge face J1a from the light-emitting element J2 from being transmitted outward.

On the other hand, when a large panel (tiling panel) is configured with a plurality of the luminescent panels planarly jointed to each other, the joint lines may be undesirably highlighted caused by the above-mentioned stray light on the edge face of the panel substrate in the respective luminescent panels. In order to address this problem, a space between the respective luminescent panels is filled up with a material having a refractive index close to that of the panel substrate or filled up with a light-absorbent or light non-transmissive material, or the edge face of the respective luminescent panels are made to be light-absorbent as described above.

Patent literature reference 1 (Japanese laid-open publication 2005-183352) shows that the joint lines between adjacent panels can be darkened and subdued by using a light scattering means provided between the opposing edge faces of adjacent panels, when producing an illuminating device capable of illuminating a broad area by combining a plurality of the luminescent panels with EL elements.

### PRIOR ART

Patent Literature

Patent Literature 1: Japanese laid-open publication 2005-183352

### SUMMARY OF THE INVENTION

### Problems Solved by the Invention

When using the above-mentioned luminescent panel, such as an organic EL panel, as a display panel, an invisible area occurs on a display screen of a luminescent panel corresponding to the thickness of the panel substrate, in the case of making the edge face of the panel substrate to be light-absorbent, or attaching a light-absorbent or light non-transmissive member to the edge face of the panel substrate as the countermeasure against the stray light.

FIG. 2 is a view to illustrate the occurrence of the above-mentioned invisible area. FIG. 2(a) shows that a light-absorbent or light non-transmissive member S is attached to an edge face J1a of a panel substrate J1. When a display screen P is viewed over the panel substrate J1 at an angle θₒᵤₜ to to the normal line to the surface of the panel substrate J1, a viewing direction is θᵢₙ to the normal line in the panel substrate in accordance with the Snell's law nₒᵤₜ×sin θₒᵤₜ=nᵢₙ×sin θᵢₙ (nₒᵤₜ: refractive index outside of the panel substrate J1, nᵢₙ: refractive index inside of the panel substrate J1). When viewing a surface end J1e of the panel substrate J1 at the angle θₒᵤₜ, the invisible area is the outside portion f of the actual viewable point T on the display screen (on the back surface of the panel substrate J1), thus the portion f becomes a missing portion of the display screen image.

The actual refractive index nᵢₙ inside the panel substrate J1 is approximately 1.5 for a glass panel substrate, while the actual refractive index nₒᵤₜ outside of the panel substrate is 1.0 for an air. As shown in FIG. 2(b), θᵢₙ is a total reflection critical angle θ_{c} when θₒᵤₜ=90° is applied as the maximum viewing angle. θᵢₙ is represented as follows:

θᵢₙ=sin⁻¹{(n_{out/}nᵢₙ)×sin 90°}=sin⁻¹(1/1.5)×1=41.8°≡θ_{c}

If t₀=d×tan θ_{c}≦w as shown in FIG. 2(b), where the thickness of the panel substrate is d and a distance from the lateral surface J1a to the display screen P is w (margin), the missing portion of the display screen does not exist in principle.

Thus, the missing portion of the display screen caused by the edge face J1a of the panel substrate J1 being light-absorbent or light non-transmissive occurs depending on the relations between the thickness d of the panel substrate, the refractive index of the panel substrate (total reflection critical angle θ_{c}) and the distance w (margin) from the edge face J1a to the display screen P. Further, if the display screen is formed by a plurality of pixels arranged in a matrix and the relation between the margin w and t₀=d×tan θ_{c} is t₀>w as shown in FIG. 3, the first row of pixels close to the edge face that is made to be light-absorbent or light non-transmissive is subject to the above-mentioned “missing”, thus a part of the first row of pixel Pi may be lost in the region of t₁=t₀−w as shown in FIG. 3.

When the display screen P produces a color display by mixing a plurality of pixel colors such as RGB, if a part of Pi is lost as shown in FIG. 3, the mixing ratio of the color corresponding to the lost display pixels is reduced, thus a desired colored may not be produced. Further, when a tiling panel is configured with a plurality of the luminescent panel planarly jointed to each other, the respective luminescent panels are subject to the above-mentioned “missing”, thus, the joint lines may be significantly and undesirably highlighted.

On the other hand, when the luminescent panel is incorporated in various devices or is installed alone, the outside region of the display screen P (margin) that is not used for display is requested to be minimized so as not to dominate the peripheral space. In addition, in the case that a plurality of display screens are formed on a large-sized panel substrate to produce multiple pieces of the panel, the number of the panel produced from one large-sized panel substrate is reduced as the margin becomes larger, thus manufacturing yield may be reduced and productivity may not be effectively improved. Furthermore, in the case that a large-sized panel is configured with a plurality of luminescent panels being arranged together, the marginal region of the respective luminescent panels forms non light-emitting regions located over the entire display screen, thus the minimization of the marginal region has been requested to improve the display performance of the display screen.

If the marginal region of the luminescent panel is minimized upon the request as described above, the distance w from the edge face J1a to the display screen P is inevitably reduced, and the above-mentioned condition t₀=d×tan θ_{c}≦w cannot be realized. In other words, in the luminescent panel where the stray light on the edge face of a panel substrate is restricted, the above-mentioned issue of “missing portion” of the display screen may appear when the marginal region is intended to be narrowed.

The present invention is devised to address the problem as described above. An objective of the present invention is to provide a high-grade color display by restricting a reduced mixed color ratio when producing a color display with mixed color pixels, while improving the display performance by restricting the stray light on the edge face of the panel in an organic EL panel (luminescent panel) where a display screen is formed with a plurality of pixels. Another objective of the present invention is to improve the display grade of the entire large-scaled display screen with the joint lines of the respective luminescent panels being subdued, when configuring a tiling panel with a plurality of the organic EL panels (luminescent panels) planarly jointed to each other. Still another objective of the present invention is to restrict a reduced display performance caused by the “missing portion” of the display screen while pursuing a narrower marginal region in an organic EL panel (luminescent panel) where stray light on the edge face of the panel is restricted.

### MEANS FOR SOLVING PROBLEM

In order to achieve the objectives described above the present invention includes at least elements defined in the independent claims.

According to one aspect of the present invention, an organic EL panel includes an organic EL element having an anode, an organic layer and a cathode laminated on one side of a panel substrate. The organic EL panel transmits light from the organic EL element outward through the panel substrate or a sealing substrate for sealing the organic EL element. The right and left edge faces of the panel substrate or the sealing substrate are made to be light-absorbent or light non-transmissive. The light-emitting surface of the organic EL element is configured in a horizontally elongated shape with a longitudinal direction orthogonal to a direction along the right and left edge faces.

According to another aspect of the present invention, a panel-combined light-emitting device includes a plurality of the organic EL panels planarly jointed to each other. The organic EL panel is configured to transmit light emitted from an organic EL element outward through a panel substrate or a sealing substrate for sealing the organic EL element. The organic EL element includes an anode, an organic layer and a cathode laminated on one surface of the panel substrate. The right and left edge faces of the panel substrate or the sealing substrate are made to be light-absorbent or light non-transmissive. The light-emitting surface of the organic EL element is configured in a horizontally elongated shape with a longitudinal direction orthogonal to a direction along the right and left edge faces.

### BRIEF DESCRIPTION OF THE DRAWINGS

FIG. 1 is a view for illustrating stray light and a countermeasure against the stray light of a luminescent panel.

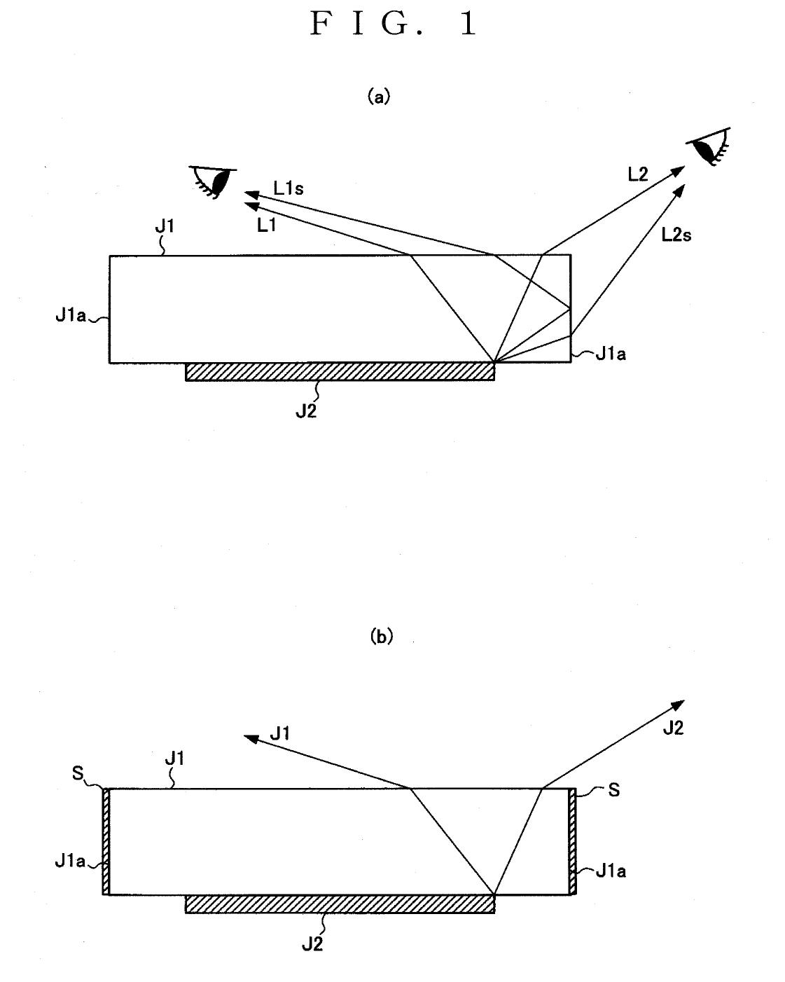

FIG. 2 is a view for illustrating an occurrence of an invisible area of the luminescent panel.

FIG. 3 is a view for illustrating a “missing portion” of a display screen of the luminescent panel when the display screen is configured with a plurality of pixels arranged in a matrix in a plane.

FIG. 4 is a view for illustrating a feature of an organic EL panel according to one embodiment of the present invention (plan view). FIG. 4(a) shows that R, G and B pixels are arranged in series along X-axis direction, while FIG. 4(b) shows those pixels arranged in series along Y-axis direction.

FIG. 5 is a view for illustrating an example of forming an organic EL element, FIG. 5(a) shows an example of an active drive element having a separate pixel electrode, while FIG. 5(b) shows an example of a passive drive element where an element is formed on a crossover portion of crossing stripe-patterned electrodes.

FIG. 6 is a view for illustrating a panel-combined light-emitting device according to one embodiment of the present invention.

FIG. 7 is a view for illustrating an example of the interconnect structure of respective organic EL panels in the panel-combined light-emitting device according to one embodiment of the present invention.

FIG. 8 is a view for illustrating an example of a polarizing plate formed on the organic EL panel according to one embodiment of the present invention. FIG. 8(a) shows the polarizing plate formed on the whole surface of a panel substrate, while FIG. 8(b) shows the polarizing plate that is narrower than the panel substrate formed on the surface of the panel substrate.

### DETAILED DESCRIPTION OF EMBODIMENTS

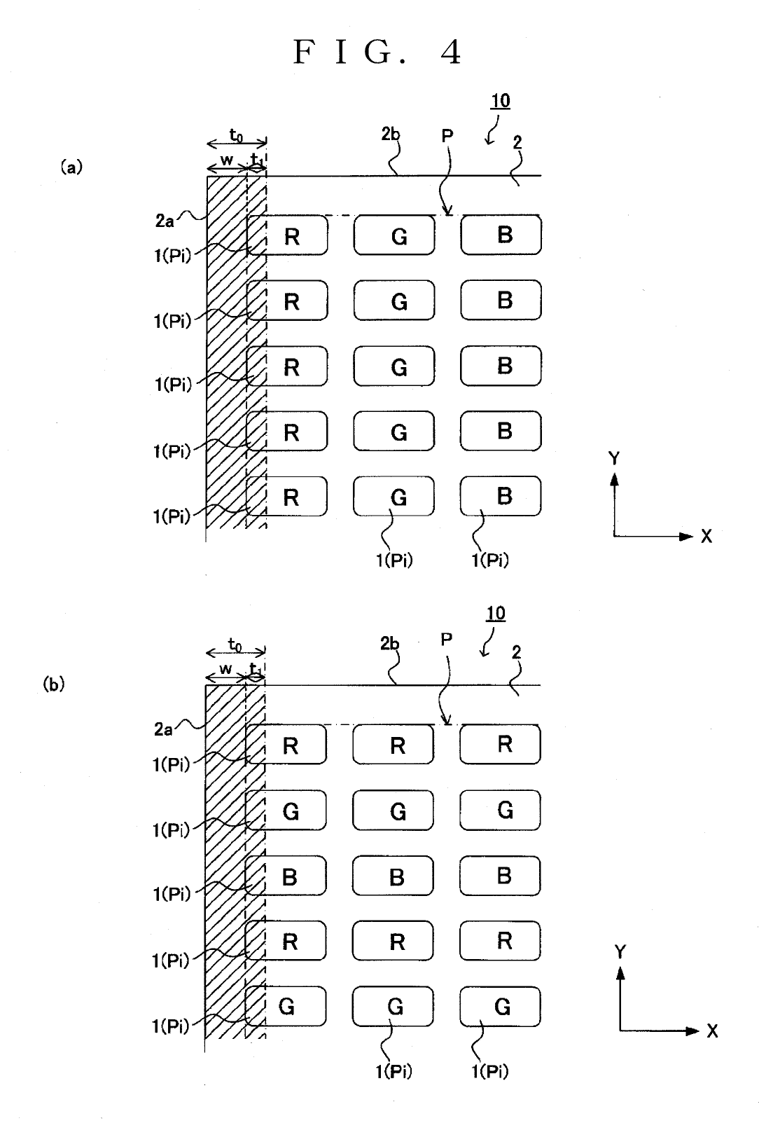

The embodiments of the present invention are described with reference to the drawings. FIGS. 4(a) and 4(b) are views for illustrating a feature of an organic EL panel according to one embodiment of the present invention (plan view). FIG. 4(a) shows that R, G and B pixels are arranged in series along the X-axis direction, while FIG. 4(b) shows those pixels arranged in series along the Y-axis direction. The organic EL panel 10 according to an embodiment of the present invention is a luminescent panel, which transmits light that is emitted from an organic EL element outward through a panel substrate 2 (bottom emission type). On the contrary, the light may be transmitted outward through a sealing substrate 3 (top emission type) or may be transmitted outward through both the panel substrate 2 and the sealing substrate 3 (dual emission type).

The organic EL panel 10 includes a display screen P formed of a plurality of pixels Pi, each pixel Pi being an organic EL element 1, Further, the right and left edge faces 2a are made to be light-absorbent or light non-transmissive. Each light-emitting surface of the organic EL element 1 is configured in a horizontally elongated shape with a longitudinal direction (X-axis direction) orthogonal to a direction (Y-axis direction) along the right and left edge faces 2a. The plurality of organic EL elements 1 are arranged along the longitudinal side (in a X-axis direction). The organic EL element 1 may be arranged individually for each color R, G and B as shown in FIG. 4(a), while multiple organic EL elements 1 may be arranged for each color R, G and B as shown in FIG. 4(b). The latter arrangement of the multiple organic EL elements 1 for each color R, G and B is more effective than former arrangement of the individual organic EL element 1 for each color in restricting a reduced mixed color ratio.

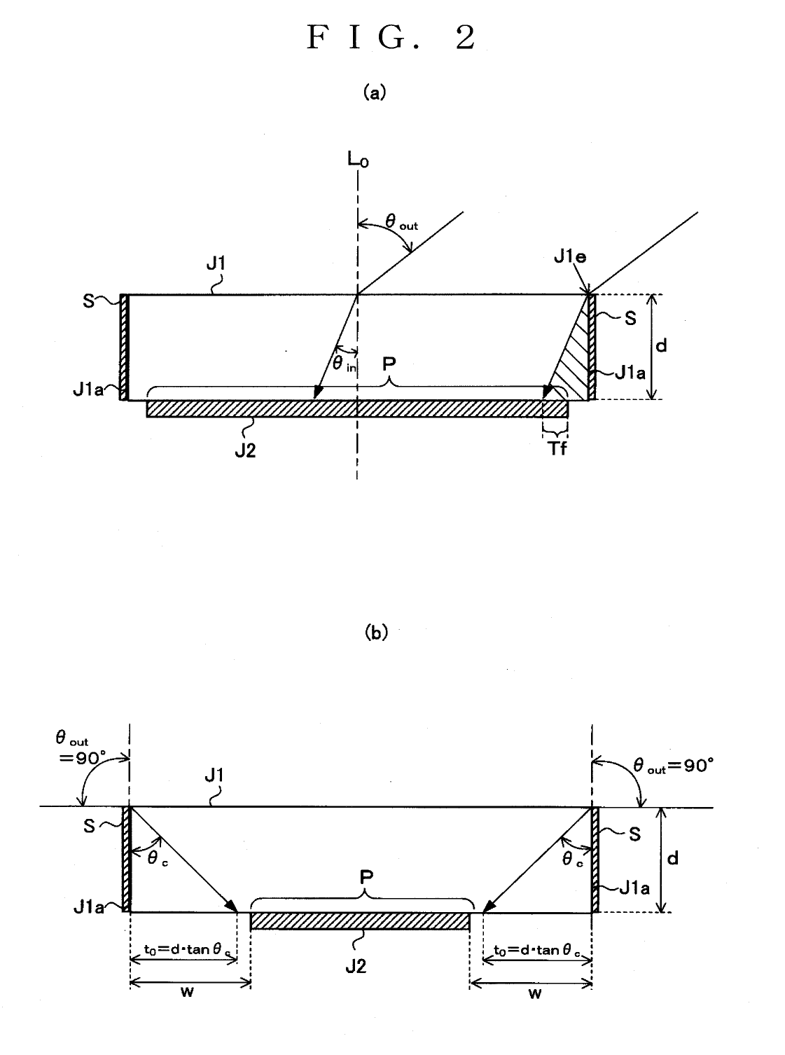

With reference to the example shown in FIG. 2, each pixel Pi formed of an organic EL element 1 is made in a rectangular shape with a longitudinal direction (X-axis direction) orthogonal to a direction (Y-axis direction) along the right and left edge faces 2a. Further, the pixels Pi formed of the organic EL elements 1 are arranged in a matrix in a plane where plural pixels are disposed in X-axis direction and Y-axis direction respectively. The right and left edge faces 2a defined in the embodiment imply the edge faces applying broader viewing angle when a user views a whole organic EL panel 10. Therefore, when a user views a vertically long organic EL panel 10, the viewing angle of the user viewing a whole organic EL panel 10 becomes broader vertically than horizontally, thus the above-mentioned right and left edge faces 2a may imply the top and bottom edge faces.

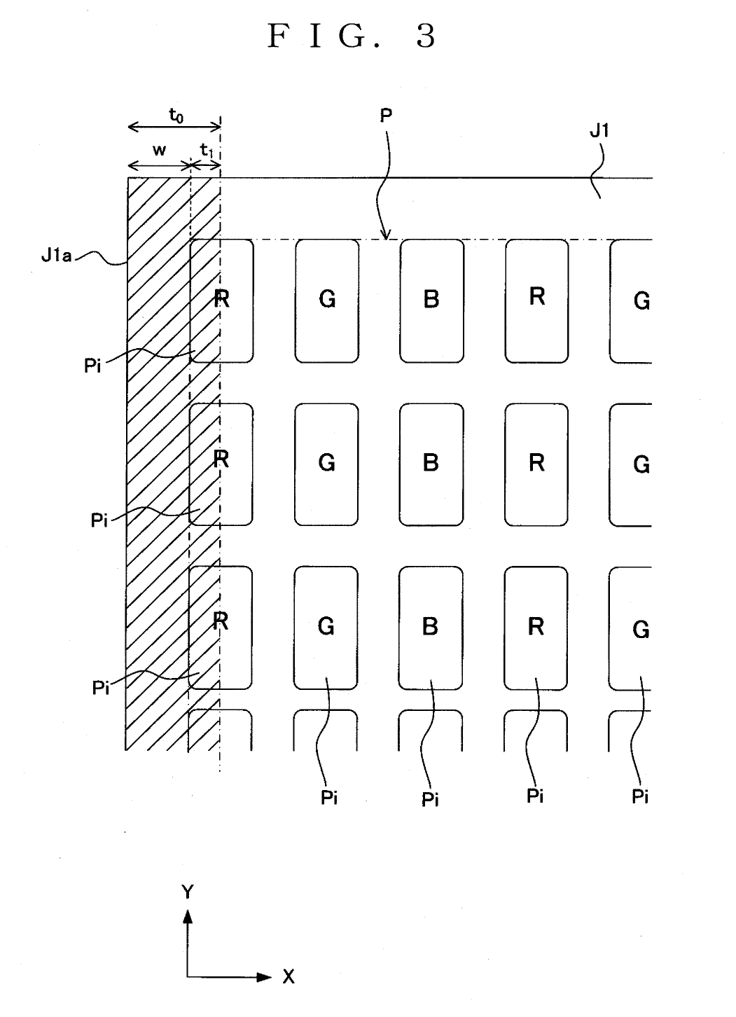

In the organic EL panel 10 described above, when considering the occurrence of the above-mentioned “missing portion” of the display screen, the missing width t₁ (=t₀−w, t₀=d×tan θ_{c}; θ_{c} is total reflection critical angle) becomes constant if the marginal width w of the display screen and, the thickness d and diffraction index of the panel substrate 2 are constant, Since the light-emitting surface of the organic EL element 1 is configured in a horizontally elongated shape with a longitudinal direction (X-axis direction) orthogonal to a direction (Y-axis direction) along the right and left edge faces 2a, the ratio of the missing area to the whole area of the pixel is smaller than for example, the vertically elongated shape as shown in FIG. 3 if the missing width t₁ is same. Accordingly, the display screen is less susceptible to the “missing portion.”

More specifically, if the pixel Pi is configured to be in a horizontally elongated shape with a longitudinal direction (X-axis direction) orthogonal to a direction (Y-axis direction) along the right and left edge faces 2a as shown in FIG. 4, the display screen may be adapted to be less affected by the “missing portion” than if the pixel Pi is configured to be in a vertically elongated shape with its longitudinal direction (Y-axis direction) along the right and left edge faces 2a as shown in FIG. 3, provided that the conditions of constructing the organic EL panel 10 (marginal width w of display screen, thickness d of panel substrate, refractive index) are the same and the display performance (image resolution) is the same, by employing the same size and shape of pixel Pi.

The “missing portion” of the display screen occurs when the top and bottom edge faces 2b are made to be light-absorbent or light non-transmissive as well. However, the display devices are generally made in a horizontally elongated shape. When viewing the display screen of such display devices, the viewing angle is broader horizontally than vertically, thus the above-mentioned inconvenience of the “missing portion” becomes significant. Thus, considering the horizontally elongated display devices, the display screen may be adapted to be less affected by the “missing portion” by making the emitting surface of the organic EL element 1 in a horizontally elongated shape.

In the organic EL panel 10, in order to make the right and left edge faces 2a to be light-absorbent or light non-transmissive, the right and left edge faces 2a are stained by a color that absorbs visible light emitted from the organic EL element or attached by a member absorbing or not transmitting the visible light from the organic EL element. In the case that a tiling panel is configured as described later, it is required to make the space between the organic EL panels 10 narrower than ever, thus advantageously no members are provided between the panels. In that case, the right and left lateral surfaces 2a are preferably stained by a color that absorbs the visible light emitted from the organic EL element.

Further, in the organic EL panel 10, when the display panel P displays a color image with mixed colors created by plural different colors of pixels, the ratio of the “missing portion” to the whole area of the pixel is minimized, thus reduction of the mixed color ratio may be restricted to enable a high-grade color display to be provided. The above-mentioned color to stain the edge faces may be any color that can absorb light with a wavelength within a visual light range, and preferably may be such a color as black, grey or dark brown, which can uniformly absorb visible light within the visual light range.

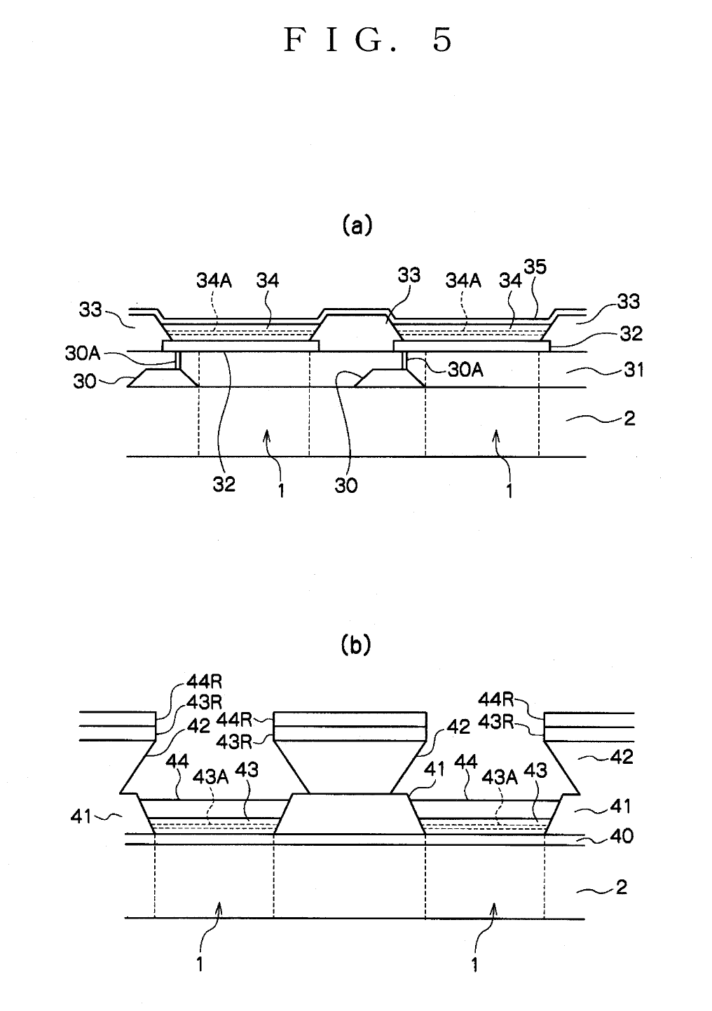

FIG. 5 is a view for illustrating an example of forming an organic EL element. The organic EL element 1 has a structure where an anode, an organic layer and a cathode are serially laminated on one surface of the panel substrate 2. FIG. 5(a) shows an example of an active drive element having a separate pixel electrode, while FIG. 5(b) shows an example of a passive drive element where an element is formed on a crossover portion of crossing stripe-patterned electrodes.

In the example shown in FIG. 5(a), a drive element 30 (TFT, etc.) is formed on the panel substrate 2. A flat membrane 31 is formed to cover the drive element 30. And, a lower electrode 32, being a pixel electrode is formed on the flat membrane 31, The lower electrode 32 can be formed by patterning in a photolithography process after forming a membrane of an electrode material on the flat membrane 31. A connecting conductor 30A is formed to connect the lower electrode 32 to the drive element 30 and an insulating membrane 33 is formed at the periphery thereof before forming the lower electrode 32. An organic layer 34 including a light-emitting layer 34A is formed to cover an opening pattern of the insulating membrane 33 on the lower electrode 32. The organic layer 34 is mask-evaporated with a mask opening aligned with the opening of the insulating membrane 33. After that, an upper electrode 35 is formed to cover the entire organic layer 34.

In the example shown in FIG. 5(b), a lower electrode 40 is formed on the panel substrate 2 in a stripe pattern. An insulating film 41 is formed on the lower electrode 40 to make a stripe pattern so as to cross the lower electrode 40. Further, a partition 42 is formed in a stripe pattern on the insulating film 41 as necessary. The partition 42 is preferably downwardly-tapered. An organic layer 43 including a light-emitting layer 43A is formed along the stripe-patterned opening of the insulating film 41 and the partition 42. An upper electrode 44 in a stripe pattern is formed on the organic layer 43. The partition 42 serves as a mask pattern when forming the upper electrode 44. When forming films of the organic layer 43 and the upper electrode 44 thereon, an organic material deposited layer 43R and an upper electrode material deposited layer 44R are laminated on the top surface of the partition 42.

Hereinafter, an example of forming the organic layers 34 and 43 is described with the lower electrodes 32 and 40 as anodes while the upper electrodes 35 and 44 as cathodes, The lower electrodes 32 and 40 are formed by a transparent electrode such as ITO. A hole-injecting layer made of copper phthalocyanine (CuPc), etc. is formed on the lower electrodes 32 and 40 and NPB (N, N-di (naphtalence)-N, N-dipheneyl-benzidene), etc. is formed thereon as a hole transport layer. The hole transport layer functions to transport holes injected from the lower electrodes 32 and 40 to the light-emitting layers 34A and 43A. The hole transport layer may be configured with one layer or more than one layer. Further, the hole transport layer may not necessarily be formed of a single material. A single hole transport layer may be formed of plural materials. A host material having a high capacity of charge transport may be doped with a guest material having high charge-donating (-accepting) properties.

Next, the light-emitting layers 34A and 43A are formed on the hole transport layer. As one example, by using a resistance-heating evaporation method, the light-emitting layers 34A and 43A corresponding to Red, Green and Blue are formed on the respective formation regions by using masks for respective colors, An organic material emitting a red light such as a styryl pigment is used for red color such as DCM1 (4-(dicyanomethylene)-2-methyl-6-(4′-dimethylaminostyryl)-4H-pyrane). Further, an organic material emitting a green light such as Alq3 is used for green color. Furthermore, an organic material emitting a blue light such as distyryl derivative and triazole derivative is used for blue color. Other materials including a layer structure with host-guest group system may be used. For the light-emitting layer, a fluorescent material or a phosphorescent material may be used.

An electron transport layer formed on the light-emitting layers 34A and 43A are produced according to various thin-film formation methods such as the resistance-heating evaporation method, by using various materials, for example Alq3. The electron transport layer functions to transport electrons injected from the upper electrodes 35 and 44 to the light-emitting layers 34A and 43A. The electron transport layer may be configured with one layer or more than one layer. Further, the electron transport layer may not necessarily be formed of a single material. A single electron transport layer may be formed of plural materials. A host material having a high capacity of charge transport may be doped with a guest material having high charge-donating (-accepting) properties.

The insulating film 33 and 41 and the partition 42 are composed of a polyimide or a resist material. In the case that the upper electrodes 35 and 44 function as a cathode, a material with lower work function than an anode is employed. For example, if ITO is used as the anode, aluminum (Al) or a magnesium alloy (Mg—Ag) is preferably employed for the cathode. However, as Al does not have so high an electron injection efficiency, an electron injection layer such as LiF is preferably provided between Al and the electron transport layer.

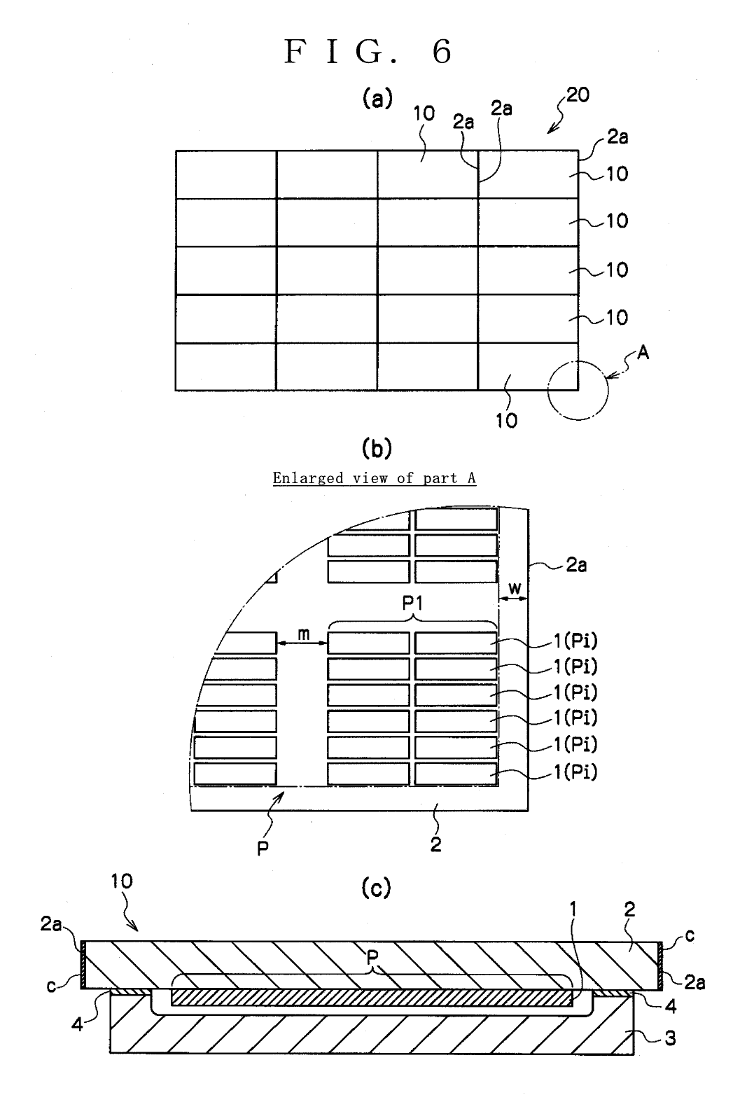

FIG. 6 is a view for illustrating a panel-combined light-emitting device 20 configured with a plurality of organic EL panels 10 planarly jointed to each other to make up a large-sized panel (FIG. 6(a) is a plan view of the panel-combined light-emitting device 20, FIG. 6(b) is an enlarged view of part A in FIG. 6(a) and FIG. 6(c) is a sectional view of the organic EL panel 10). The structure of the respective organic EL panel 10 has been described above. Each of the organic EL panels 10 is connected to the adjacent organic EL panels 10 with the left and right bottom of the edge face being faced to each other.

The panel-combined light-emitting device 20 has a plurality of the organic EL panels 10 planarly jointed to each other as shown in FIG. 6(a), producing a single or plural display screens by combining the display screens of the respective organic EL panel 10. The display screen P of the respective organic EL panel 10 is formed with a collection of plural pixels Pi as shown in FIG. 6 (b), and is adapted to enable color displaying by appropriately dispersing the organic EL elements 1 emitting different color lights such as Red (R), Green (G) and Blue (B). The display screen P of each organic EL panel 10 includes a plurality of pixel blocks P1. Each of the blocks P1 is located at a predetermined distance m from the adjacent blocks. The distance m is adapted to be approximately two times larger than the marginal width of the individual organic EL panel 10. Although the joint lines between adjacent organic EL panels 10 form a non-display part that is twice as large as the marginal width w, the joint lines can be configured to be less recognizable by providing a distance of m=about 2 w between respective pixel blocks P1.

FIG. 6(c) is a cross-sectional view showing a sealing structure of the organic EL panel 10. The organic EL panel 10 seals the organic EL element 1 formed on the panel substrate 2 by bonding a sealing substrate 3 to the panel substrate 2 via an adhesive layer 4. The sealing substrate 3 has a concave portion 3a that houses the organic EL element 1, providing a sealing space around the organic EL element 1. On the edge faces 2a, 2a of the panel substrate 2 in the organic EL panel 10, a coloring c is provided with color that absorbs visible light emitted from the organic EL element 1 as described above. The coloring c may be directly applied to the right and left edge faces 2a of the panel substrate 2 with a paint or colorant, may be applied with a colored thin film formed thereon, or may be applied with a colored member fixed thereto via an adhesive,

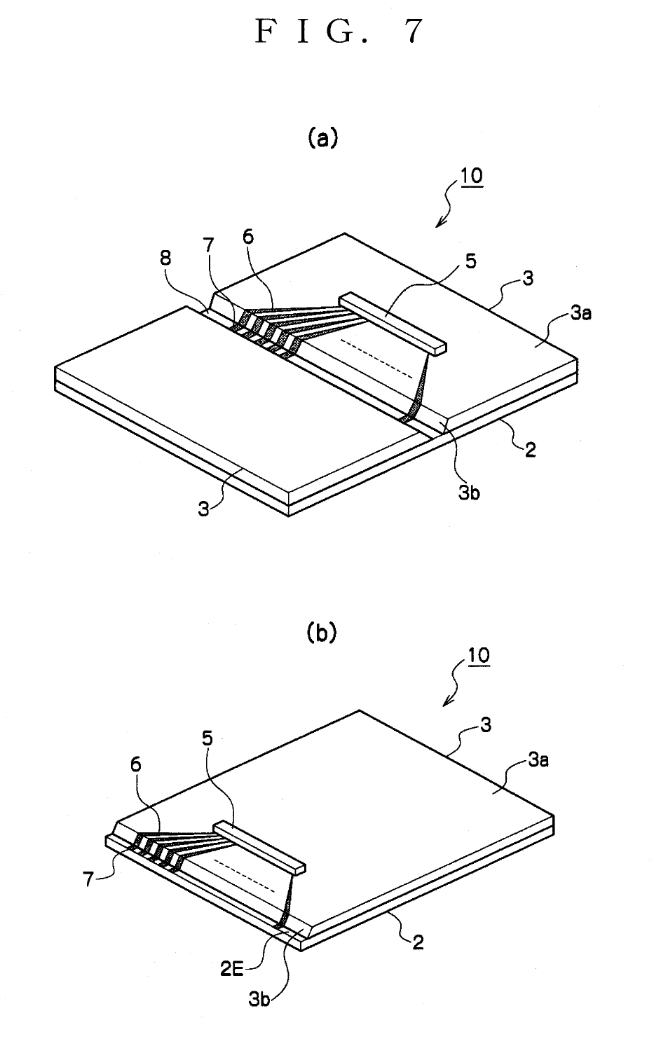

FIG. 7 is a view for illustrating an example of the interconnect structure of respective organic EL panels 10 in the panel-combined light-emitting device 20. In an example shown in FIGS. 7(a) and 7(b), a drive IC 5 is provided on the upper surface 3a of the sealing substrate 3 and a lead wire 6 is provided on the upper surface 3a and the lateral surface 3b of the sealing substrate 3. The lateral surface 3b on which the lead wire 6 is provided is formed to be tapered. The lead wire 6 on the lateral surface 3b and a lead wire 7 (a lead wire from an anode or a cathode of the organic EL element 1) on the surface of the panel substrate 2 where the organic EL element 1 is formed are connected when bonding the panel substrate 2 and the sealing substrate 3 together. The drive IC 5 being connected to the lead wire 6 on the sealing substrate 3, the drive IC 5 is connected to the organic EL element 1 via the lead wires 6 and 7. In an example shown in FIG. 7 (a), two sealing substrates 3, 3 are bonded to one panel substrate 2 to make an exposed portion 8 between the sealing substrates 3, 3. The lead wire 7 from the organic EL element 1 that is sealed by the sealing substrates 3, 3 is formed on the exposed portion 8 of the panel substrate 2. In an example shown in FIG. 7(b), one sealing substrate 3 is bonded to one panel substrate 2 to make an end portion 2E on the end of the panel substrate 2. The lead wire 7 from the organic EL element 1 that is sealed by the sealing substrate 3 is formed on the exposed portion 2E on the end of the panel substrate 2.

According to the above-mentioned panel-combined light-emitting device 20, stray light caused by light emitted from the organic EL element 1 reflecting on or passing through the right and left edge faces is effectively restricted by making the right and left edge faces of the individual organic EL panel 10 light-absorbent or light non-transmissive. Further, since the light-emitting surface of the organic EL element 1 is configured in a horizontally elongated shape with a longitudinal direction (X-axis direction) orthogonal to a direction (Y-axis direction) along the right and left edge faces 2a, the display screen may be adapted to be less affected by the “missing portion” that is caused by the right and left edge faces 2a made to be light-absorbent or light non-transmissive. In this way, reduction of the mixed color ratio in color display may be restricted with a minimized effect of the “missing portion” even when the marginal width w of the individual organic EL panel 10 is reduced.

Further, since the stray light on the edge faces of the individual organic EL panel 10 can be restricted, the brightness of the joint lines between each of the organic EL panels 10 may be subdued, thus enabling the inconvenience of visually-enhanced joint lines to be avoided, Further, since the effect of the above-mentioned “missing portion” is minimized in the individual organic EL panel 10, reduction of the mixed color ratio in color display occurring at the joint lines may be restricted, thus enabling the inconvenience of visually-enhanced joint lines to be avoided.

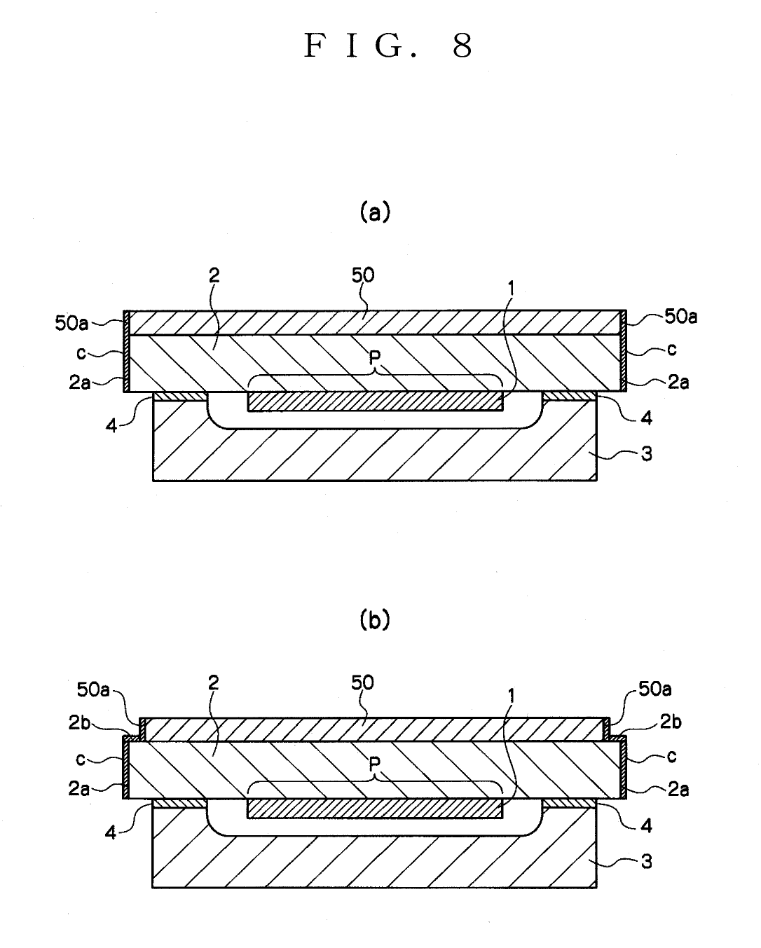

Furthermore, with a reduced marginal width w of the individual organic EL panel 10, the display grade of the panel-combined light-emitting device 20 that is configured with a plurality of the organic EL panels 10 jointed to each other may also be enhanced, In addition, a polarizing plate 50 may be provided on the surface of the organic EL panel 10 to reduce an inconvenience of external light reflecting on the upper electrode 44. The polarizing plate 50 is provided on an opposite surface to the surface of the organic EL element 1 of the panel substrate 2, and the edge face of the panel substrate 2 is flush with the edge face of the polarizing plate 50 as shown in FIG. 8(a), The edge face 50a of the polarizing plate 50 has the coloring c applied thereon, enabling to absorb visible light emitted from the organic EL element 1. The coloring c may be applied to the right and left edge faces 50a, 50a or may be applied to either one of the edge faces. Further, as shown in FIG. 8(b), when the polarizing plate 50 with a width narrower than the panel substrate 2 is employed, the coloring c is applied to the edge face 50a of the polarizing plate 50 to absorb the visible light emitted from the organic EL element 1. Further, the coloring c may be applied to a surface 2b of the panel substrate 2 that is not covered by the polarizing plate 50. The panel substrate 2 and the polarizing plate 50 can be bonded together with an adhesive or the polarizing plate 50 may be directly formed on the panel substrate 2. The panel substrate 2 may be made of a light-transmissive glass material. In a top-emission type organic EL panel 10, the polarizing plate 50 is provided on the surface of the sealing substrate 3 and the sealing substrate 3 is made of a light-transmissive glass material, etc. Although an example of using the polarizing plate 50 is shown in FIGS. 8(a) and 8(b), an optical filter for filtering out UV rays may be used as well other than the polarizing plate 50 in order to have the same effect. Furthermore, in the case that the polarizing plate 50 and the optical filter are thicker than the panel substrate 2, the inconvenience of visually-enhanced joint lines is much more reduced.

Although the embodiments of the present invention are described in detail with reference to the drawings, the specific embodiments are not limited to those described above. The scope of the present invention is intended to include all equivalents and modifications without departing from the subject matter of the present invention. Further, each of the embodiments described above may be combined to each other unless the purpose and structure are inconsistent.

1. An organic EL panel configured to transmit light emitted from an organic EL element outward through a panel substrate or a sealing substrate for sealing the organic EL element,
the organic EL element including an anode, an organic layer and a cathode laminated together on a surface of the panel substrate, wherein
right and left edge faces of the panel substrate or the sealing substrate are either light-absorbent or light non-transmissive, and
the light-emitting surface of the organic EL element is configured in a horizontally elongated shape with a longitudinal direction orthogonal to a direction along the right and left edge faces.

2. The organic EL panel according to claim 1, wherein the right and left edge faces of the panel substrate or the sealing substrate are stained by a color that absorbs visible light emitted from the organic EL element.

3. The organic EL panel according to claim 1 or 2, wherein
a display screen is configured by a plurality of pixels which are organic EL elements, the display screen is configured to display a color image with mixed colors created by plural different colors of the pixels.

4. The organic EL panel according to anyone of claims 1 to 3, wherein
the organic EL panel is a light-transmissive luminescent panel configured to transmit light emitted from an organic EL element outward through a panel substrate or a sealing substrate for sealing the organic EL element,
a polarizing plate is provided either on the panel substrate or on the sealing substrate from which light is emitted, and
an edge face of the polarizing plate is stained by a color that absorbs visible light emitted from the organic EL element.

5. A panel-combined light-emitting device having a plurality of organic EL panels planarly jointed to each other, wherein
the organic EL panel is configured
to transmit light emitted from an organic EL element outward through a panel substrate or a sealing substrate for sealing the organic EL element, the organic EL element including an anode, an organic layer and a cathode laminated together on a surface of the panel substrate, and
right and left edge faces of the panel substrate or the sealing substrate are either light-absorbent or light non-transmissive, and
a light-emitting surface of the organic EL element is configured in a horizontally elongated shape with a longitudinal direction orthogonal to a direction along the right and left edge faces.

6. The panel-combined light-emitting device according to claim 5, wherein one organic EL panel is jointed to an adjacent organic EL panel having the right and left edge faces thereof arranged face-to-face with one another,

7. The panel-combined light-emitting device according to claim 5 or 6, wherein
the organic EL panel is a light-transmissive luminescent panel configured to transmit light emitted from an organic EL element outward through a panel substrate or a sealing substrate for sealing the organic EL element,
a polarizing plate is provided either on the panel substrate or on the sealing substrate from which light is emitted, and an edge face of the polarizing plate is stained by a color that absorbs visible light emitted from the organic EL element.
